(19) United States
(12) Patent Application Publication
(10) Pub. No.: US 2025/0226641 A1
(43) Pub. Date: Jul. 10, 2025

(54) NANO BESSEL LASER BEAM EMITTER AND METHOD FOR MANUFACTURING THE SAME

(71) Applicant: SOUTHERN UNIVERSITY OF SCIENCE AND TECHNOLOGY, Shenzhen, Guangdong (CN)

(72) Inventors: Xiaowei SUN, Shenzhen, Guangdong (CN); Lars SAMUELSON, Shenzhen, Guangdong (CN); Haodong TANG, Shenzhen, Guangdong (CN); Pai LIU, Shenzhen, Guangdong (CN); Yifan LIU, Shenzhen, Guangdong (CN); Jingrui MA, Shenzhen, Guangdong (CN)

(73) Assignee: SOUTHERN UNIVERSITY OF SCIENCE AND TECHNOLOGY, Shenzhen, Guangdong (CN)

(21) Appl. No.: 18/844,496

(22) PCT Filed: Apr. 15, 2022
(86) PCT No.: PCT/CN2022/086936

§ 371 Date: Sep. 6, 2024

(30) Foreign Application Priority Data
Mar. 9, 2022 (CN) 202210230168.6

(51) Int. Cl. H01S 5/125; H10H 20/01; H10H 20/813; H10H 20/841

(52) U.S. Cl. CPC H01S 5/125; H10H 20/034; H10H 20/813; H10H 20/841

(57) ABSTRACT

A nano Bessel laser beam emitter and a method for manufacturing the same are disclosed. The nano Bessel laser beam emitter includes a first Bragg reflecting layer, a light-emitting layer and a second Bragg reflecting layer, where the first Bragg reflecting layer defines a cylindrical through hole; the light-emitting layer is provided on a surface of the first Bragg reflecting layer and is configured to generate a light beam; and the second Bragg reflecting layer is provided on the light-emitting layer at a side distal to the first Bragg reflecting layer.

### CROSS-REFERENCE TO RELATED APPLICATION

This application is a national stage filing under 35 U.S.C. § 371 of international application number PCT/CN2022/086936, filed Apr. 15, 2022, which claims priority to Chinese patent application No. 202210230168.6 filed Mar. 9, 2022. The contents of these applications are incorporated herein by reference in their entirety.

### TECHNICAL FIELD

The present application relates to the technical field of semiconductor optoelectronic devices, in particular to a nano Bessel laser beam emitter and a method for manufacturing the same.

### BACKGROUND

As a non-diffracting beam, a Bessel beam has a special property that the initial optical field is invariant in any plane perpendicular to the propagation direction. In recent years, the Bessel beam has been widely used in laser cutting, laser precision collimation, ranging, navigation and other fields.

At present, the Bessel beams are generally generated through an annular slit method, a holographic method, a conical lens method and a spherical aberration method. However, the central peak radius of the Bessel beam generated by these methods is limited within the order of micrometer, while the size of the devices for generating the Bessel beams is large, so it is not possible to integrate these devices.

### SUMMARY

The present application is intended to solve at least one of the technical problems existing in the existing technology. To this end, the present application provides a nano Bessel laser beam emitter, which can generate a Bessel beam with a central peak radius of the order of nanometer, has a simple structure, and can realize integration.

The present application further provides a method for manufacturing a nano Bessel laser beam emitter.

According to an embodiment of a first aspect of the present application, provided is a nano Bessel laser beam emitter, which includes: a first Bragg reflecting layer defining a cylindrical through hole; a light-emitting layer provided on a surface of the first Bragg reflecting layer and configured to generate a light beam; and a second Bragg reflecting layer provided on the light-emitting layer at a side distal to the first Bragg reflecting layer.

According to the nano Bessel laser beam emitter as set forth in an embodiment of the present application, the nano Bessel laser beam emitter at least has the following effects that cylindrical through holes are formed in the first Bragg reflecting layer, so that a Bessel beam with a nano-scale light-emitting light spot is generated after a beam is subjected to multiple reflections of the first Bragg reflecting layer and the second Bragg reflecting layer, thereby improving the dimensional stability of the Bessel beams. Meanwhile, the nano Bessel laser beam emitter is simple in structure and small in size, and can realize the integration of miniaturized light sources.

According to some embodiments of the present application, each of the first Bragg reflecting layer and the second Bragg reflecting layer includes a plurality of reflecting layers, and the first Bragg reflecting layer includes a larger number of reflecting layers than the second Bragg reflecting layer; and each reflecting layer includes a high refractive material layer and a low refractive material layer.

According to some embodiments of the present application, the nano Bessel laser beam emitter further includes a substrate provided on the first Bragg reflecting layer at a side distal to the light-emitting layer.

According to some embodiments of the present application, the nano Bessel laser beam emitter further includes a growth layer provided on the substrate at a side adjacent to the first Bragg reflecting layer, and a connecting part including an extending piece and a supporting piece, where the extending piece is embedded in the cylindrical through hole of the first Bragg reflecting layer, and the supporting piece is provided on the first Bragg reflecting layer at a side distal to the growth layer.

According to some embodiments of the present application, the supporting piece is of a hexagonal frustum structure, has a larger area at a surface adjacent to the growth layer than that of a surface distal to the growth layer, and the light-emitting layer is provided on the supporting piece at the surface distal to the growth layer.

According to some embodiments of the present application, the light-emitting layer includes an LED light source provided on the first Bragg reflecting layer at a side adjacent to the second Bragg reflecting layer and corresponding to the cylindrical through hole, and an electrode provided on the LED light source at a side distal to the first Bragg reflecting layer and configured to supply power to the LED light source.

According to some embodiments of the present application, the nano Bessel laser beam emitter further includes an anti-oxidation layer provided between the LED light source and the electrode and covering a lateral surface of the LED light source.

According to some embodiments of the present application, the LED light source is a respective one of a plurality of LED light sources, and the nano Bessel laser beam emitter further includes a plurality of isolation layers each covering a surface of the anti-oxidation layer of a respective one of the plurality of LED light sources and configured to separate light beams emitted by two adjacent LED light sources of the plurality of the LED light sources.

According to an embodiment of a second aspect of the present application, provided is a method for manufacturing a nano Bessel laser beam emitter, which includes the following steps: sequentially providing a growth layer and a first Bragg reflecting layer on a surface of a substrate by a plasma-enhanced chemical vapor deposition method, a low pressure chemical vapor deposition method or a magnetron sputtering method; etching the first Bragg reflecting layer to generate a cylindrical through hole; depositing a semiconductor material on a surface of the first Bragg reflecting layer by an metal-organic chemical vapor deposition method to form a connecting part, where the connecting part includes an extending piece and a supporting piece; growing an LED structure on a surface of the supporting piece to generate an LED light source; providing an electrode on a surface of the LED light source by a thermal evaporation method, thus forming a light-emitting layer including the LED light source and the electrode; and providing a second Bragg reflecting layer on a surface of the light-emitting layer.

The method for manufacturing the nano Bessel laser beam emitter as set forth in an embodiment of the present application at least has the following effects that the nano Bessel laser beam emitter generated by the method is small in size and convenient to realize integration; and meanwhile, the manufacturing method is simple, and the large-scale production of the nano Bessel laser beam emitter can be realized.

According to some embodiments of the present application, the method further includes the following steps: depositing a metal oxide film on a lateral surface of the LED light source to form an anti-oxidation film, and providing a polymer material on a surface of the anti-oxidation film to form an isolation layer.

Additional aspects and advantages of the present application will be set forth in part in the description below and, in part, will be apparent from the description below, or may be learned by practice of the present application.

### BRIEF DESCRIPTION OF THE DRAWINGS

The present application will be further described below with reference to the accompanying drawings and embodiments, in which:

FIG. 1 is a schematic diagram depicting the structure of a nano Bessel laser beam emitter according to an embodiment of the present application;

FIG. 2 is a schematic diagram depicting detailed structures of the first Bragg reflecting layer in FIG. 1;

FIG. 3 is a schematic diagram depicting detailed structures of the second Bragg reflecting layer in FIG. 1;

FIG. 4 is another schematic diagram depicting a nano Bessel laser beam emitter according to an embodiment of the present application;

FIG. 5 is a schematic diagram depicting the detailed structures of the connecting part in FIG. 4;

FIG. 6 is a schematic flow chart of a method for manufacturing a nano Bessel laser beam emitter according to an embodiment of the present application; and

FIG. 7 is another schematic flow chart of a method for manufacturing a nano Bessel laser beam emitter according to an embodiment of the present application.

### REFERENCE NUMERAL LIST

First Bragg reflecting layer 100,
Cylindrical through hole 110,
Reflecting layer 120,
High refractive material layer 121,
Low refractive material layer 122,
Light-emitting layer 200,
LED light source 210,
Electrode 220,
Second Bragg reflecting layer 300,
Substrate 400,
Growth layer 500,
Connecting part 600,
Extending piece 610,
Supporting piece 620,
Anti-oxidation layer 700, and
Isolation layer 800.

### DETAILED DESCRIPTION

Embodiments of the present application are described in detail below, examples of which are illustrated in the accompanying drawings, where identical or similar reference numerals represent identical or similar elements or elements having identical or similar functions throughout. The embodiments described below with reference to the accompanying drawings are illustrative only for the purpose of explaining the present application and are not to be construed as limiting the present application.

In the description of the present application, it should be understood that the description related to the orientation, such as the orientation or positional relationship indicated by up, down, front, back, left, right, etc., is based on the orientation or positional relationship shown in the accompanying drawings, which is only for the convenience of describing the present application and simplifying the description. It is not intended to indicate or imply that the devices or elements referred to must have a particular orientation, be constructed and operated in a particular orientation, and therefore should not be construed as limiting the present application.

In the description of the present application, the meaning of “several” is more than one, the meaning of “a plurality of” is more than two, “greater than”, “less than”, “exceeding”, etc. are to be interpreted as excluding this number as mentioned, and above, below, within, etc. are be interpreted as including this number as mentioned. Terms “first” and “second”, if described, are only for the purpose of distinguishing the technical features, and shall not be construed to indicate or imply relative importance or to implicitly indicate the number of the indicated technical features or to implicitly indicate the sequential relationship of the indicated technical features.

In the description of the present application, unless otherwise expressly defined, terms such as “setting”, “installation”, and “connection” should be interpreted in a broad sense, and those skilled in the art can reasonably determine the specific meanings of the above terms in the present application in combination with the specific contents of the technical solution.

In the description of the present application, reference to a description of “an embodiment”, “some embodiments”, “illustrative embodiments”, “an example”, “a specific example”, or “some examples” or the like means that a particular feature, structure, material, or characteristic described in conjunction with the embodiment or example is included in at least one embodiment or example of the present application. In the present specification, schematic expressions of the above terms are not necessarily referring to the same embodiment or example. Moreover, the particular features, structures, materials, or characteristics described may be combined in any suitable manner in any one or more embodiments or examples.

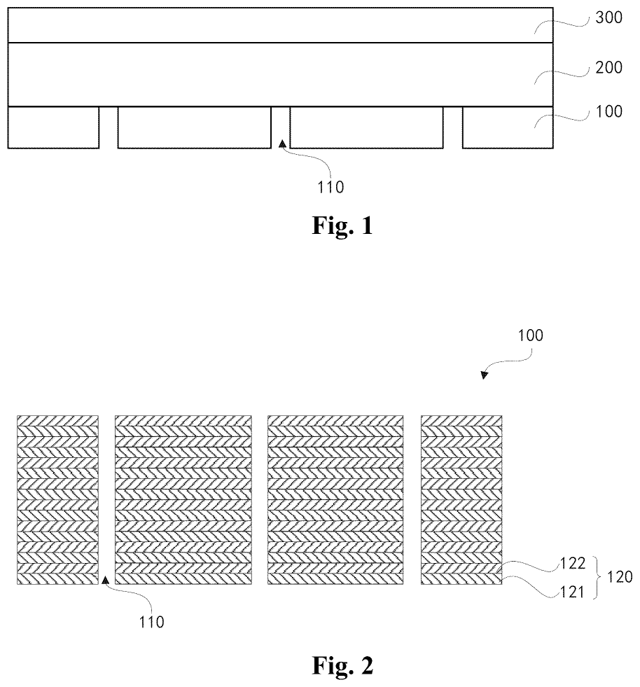

A nano Bessel laser beam emitter according to an embodiment of the present application is described below with reference to FIG. 1.

As shown in FIG. 1, the nano Bessel laser beam emitter according to the embodiment of the present application includes a first Bragg reflecting layer 100, a light-emitting layer 200, and a second Bragg reflecting layer 300, where the first Bragg reflecting layer 100 defines cylindrical through holes 110. The light-emitting layer 200 is disposed on a surface of the first Bragg reflecting layer 100 and is configured to generate light beams. The second Bragg reflecting layer 300 is disposed on a side which is distal to the first Bragg reflecting layer 100, of the light-emitting layer 200.

Specifically, as shown in FIG. 1, the first Bragg reflecting layer 100 and the second Bragg reflecting layer 300 are of rectangular plate-like structures substantially, and the first Bragg reflecting layer 100 definesh cylindrical through holes 110. Light beams emitted by the light-emitting layer 200 are propagated in a cavity formed by the first Bragg reflecting layer 100 and the second Bragg reflecting layer 300 and are continuously reflected. Due to the presence of the cylindrical through holes 110 in the first Bragg reflecting layer 100, an annular and hollow Bessel light spot is eventually formed. The diameters of the cylindrical through holes 110 may determine the size of the emitting light spot. Due to the sizes of the cylindrical through holes 110 between 50 nm and 300 nm, the size of a beam spot generated after the beam is reflected by the first Bragg reflecting layer 100 and the second Bragg reflecting layer 300 is on the order of nanometer. By adjusting the sizes of the cylindrical through holes 110, the size of the center peak radius of the Bessel beam can be adjusted.

According to the nano Bessel laser beam emitter according to an embodiment of the present application, the cylindrical through holes 110 are formed in the first Bragg reflecting layer 100, so that a Bessel beam with a nano-scale emitting light spot is generated after the beam is subjected to multiple reflections by the first Bragg reflecting layer 100 and the second Bragg reflecting layer 300, thereby improving the dimensional stability of the Bessel beam. Meanwhile, the nano Bessel laser beam emitter is simple in structure and small in size, and can realize the integration for miniaturized light sources.

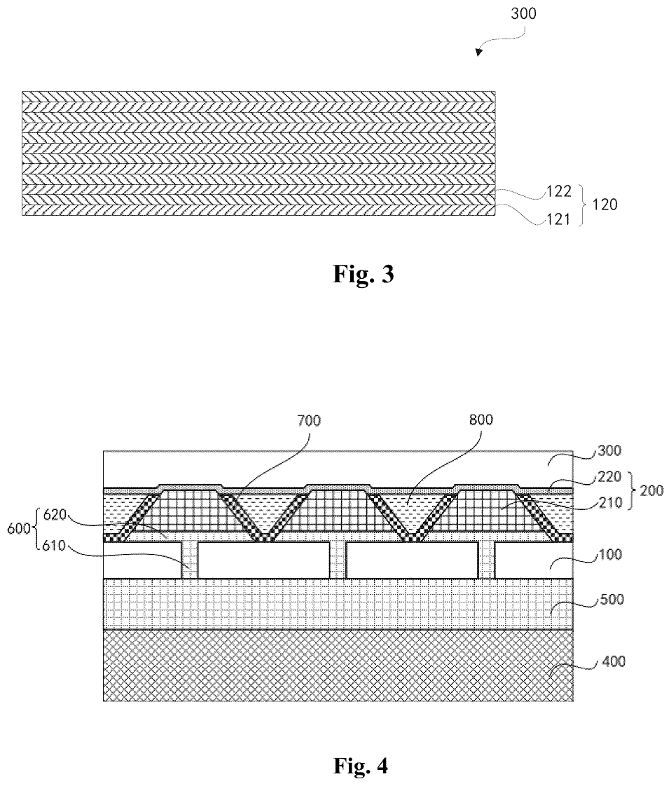

In some embodiments of the present application, as shown in FIG. 1 to FIG. 3, both the first Bragg reflecting layer 100 and the second Bragg reflecting layer 300 include a plurality of reflecting layers 120, and the first Bragg reflecting layer 100 includes a larger number of reflecting layers 120 than that of the second Bragg reflecting layer 300. And each reflecting layer 120 includes a high refractive material layer 121 and a low refractive material layer 122.

Specifically, as shown in FIGS. 1 to 3, the first Bragg reflecting layer 100 is composed of eight reflecting layers 120, and the second Bragg reflecting layer 300 is composed of six reflecting layers 120. Since the first Bragg reflecting layer 100 includes a larger number of reflecting layers 120 than that of the second Bragg reflecting layer 300, light beams emitted from the light-emitting layer 200 are subjected to multiple reflections by the first Bragg reflecting layer 100 and the second Bragg reflecting layer 300, and then emitted from the second Bragg reflecting layer 300. Each reflecting layer 120 is composed of a high refractive material layer 121 and a low refractive material layer 122, and the high refractive material layers 121 and the low refractive material layers 122 are alternately disposed. The high refractive material layers 121 may be made of a material with a high refractive index such as silicon nitride, and the low refractive material layers 122 may be made of a material with a low refractive index such as silicon dioxide. It can be understood that the number of the reflecting layers 120 included in the first Bragg reflecting layer 100 and the second Bragg reflecting layer 300 can be set as required.

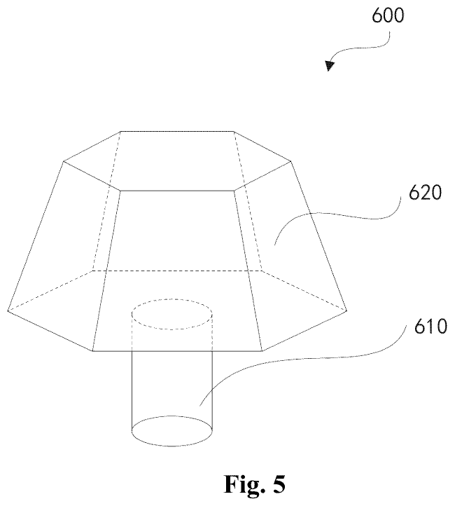

In some embodiments of the present application, as shown in FIG. 4, the nano Bessel laser beam emitter further includes a substrate 400 disposed on the first Bragg reflecting layer 100 at a side distal to the light-emitting layer 200. Specifically, the substrate 400 is disposed on the first Bragg reflecting layer 100 at a side distal to the light-emitting layer 200. The substrate 400 is of a substantially rectangular plate-like structure and is configured to support other structures in the nano Bessel laser beam emitter. In the present application, the substrate 400 is made of sapphire, which has the advantages of good stability, high mechanical strength, and the like. It can be understood that the substrate 400 can also be made of other semiconductor materials, such as silicon and gallium arsenide.

In some embodiments of the present application, as shown in FIG. 4 and FIG. 5, the nano Bessel laser beam emitter further includes a growth layer 500 and connecting parts 600, where the growth layer 500 is disposed on the substrate 400 at a side adjacent to the first Bragg reflecting layer 100. Each of the connecting parts 600 includes an extending piece 610 and a supporting piece 620, where the extending piece 610 is embedded in the cylindrical through holes 110 of the first Bragg reflecting layer 100, and the supporting piece 620 is disposed on the first Bragg reflecting layer 100 at a side distal to the growth layer 500.

Specifically, as shown in FIG. 4 and FIG. 5, the growth layer 500, which has the identical shape and size as the substrate 400, is disposed on the substrate 400 at a side adjacent to the first Bragg reflecting layer 100. The growth layer 500 is made of gallium nitride, and it can be understood that the material may be varied as required. The connecting parts 600 are grown above the growth layer 500, and each includes two parts, that is, the extending piece 610 and the supporting piece 620. The extending pieces 610 are of a cylindrical structure, and the cylindrical through holes 110 of the first Bragg reflecting layer 100 are filled with the extending pieces 610. The supporting pieces 620 are disposed on the first Bragg reflecting layer 100 at a side distal to the growth layer 500, and are connected to the extending piece. A light-emitting material may be grown on a surface of the supporting pieces 620 to form the light-emitting layer 200. The lengths and the widths of the supporting pieces 620 are both larger than the diameters of the cylindrical through holes 110, the area of the supporting pieces 620 is about 5 to 20 times as large as that of the cylindrical through holes 110, and the sizes of the supporting pieces 620 can be particularly set as required.

In some embodiments of the present application, as shown in FIG. 4 and FIG. 5, each supporting piece 620 is of a hexagonal frustum structure. The supporting piece 620 has a larger area at the surface adjacent to the growth layer 500, than that of the surface distal to the growth layer 500. The light-emitting layer 200 is disposed on the supporting piece 620 at the surface distal to the growth layer. Specifically, the supporting piece 620 of the connecting part 600 is of a hexagonal frustum structure. The supporting piece 620 has a larger area at the hexagonal surface connected with the extending piece 610, than that of the opposite hexagonal surface. The light-emitting layer 200 may be grown on supporting piece 620 at the hexagonal surface distal to the growth layer 500, and the hexagonal bottom surface serves as a patterned substrate for the growth of the light-emitting layer 200.

In some embodiments of the present application, as shown in FIG. 4, the light-emitting layer 200 includes LED light sources 210 and an electrode 220, where each LED light source 210 is disposed on the first Bragg reflecting layer 100 at one side adjacent to the second Bragg reflecting layer 300, and each disposed corresponding to a cylindrical through hole 110; and the electrode 220 is disposed on the LED light sources 210 at one side distal to the first Bragg reflecting layer 100 for supplying power to the LED light sources 210. Specifically, the light-emitting layer 200 includes LED light sources 210 and an electrode 220, and LED structures are grown on the supporting pieces 620 at one side distal to the first Bragg reflecting layer 100, thereby the LED light sources 210 capable of emitting light beams outward are thus generated. The LED light sources 210 are positioned above the cylindrical through holes 110, so that the light beams emitted by the LED light sources can be modulated by the cylindrical through holes 110 to generate Bessel beams of nanometer scale. The electrode 220 is disposed on the LED light sources 210 at one side distal to the first Bragg reflecting layer 100, and the LED light sources 210 are powered by the electrode 220 to emit light beams.

In some embodiments of the present application, as shown in FIG. 4, the nano Bessel laser beam emitter further includes anti-oxidation layers 700 each disposed between its respective LED light source 210 and the electrode 220 and covering a lateral surface of the respective LED light source 210. Specifically, each anti-oxidation layer 700 is disposed between an LED light source 210 and an electrode 220, and covers the lateral surface of the LED light source 210, so as to protect the LED light source 210 from being oxidized and damaged. In the present application, the anti-oxidation layers 700 are made of aluminum oxide. It can be understood that the anti-oxidation layers 700 can also be made of other metal oxide films. In addition, since the anti-oxidation layers 700 cover the lateral surfaces of the LED light sources 210, the light beams emitted by the LED light sources 210 can be prevented from propagating towards both sides, such that more light beams can enter the first Bragg reflecting layer 100, which increases the utilization rate of the light beams.

In some embodiments of the present application, as shown in FIG. 4, the nano Bessel laser beam emitter further includes isolation layers 800 each covering a surface of an anti-oxidation layer 700 for separating the light beams emitted by the two adjacent LED light sources 210. Specifically, each of the isolation layers 800 covers a surface of an anti-oxidation layer 700, and the electrode 220 covers the surfaces of the LED light sources 210, the anti-oxidation layers 700, and the isolation layers 800. The isolation layers 800 can separate the two adjacent LED light sources 210, so as to prevent the light beams emitted by the LED light sources 210 from being mixed to affect the quality of the Bessel beams. The isolation layers 800 may be made of a polymer material.

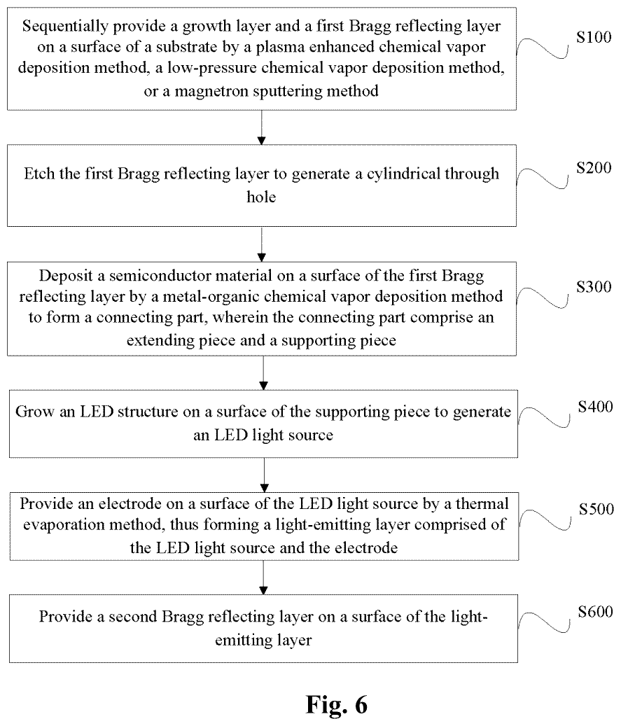

In some embodiments, the present application further provides a method for manufacturing a nano Bessel laser beam emitter, as shown in FIG. 6, the method includes but is not limited to the following steps.

In S100, sequentially providing a growth layer and a first Bragg reflecting layer on the surface of a substrate by a plasma-enhanced chemical vapor deposition method, a low-pressure chemical vapor deposition method, or a magnetron sputtering method.

In S200, etching the first Bragg reflecting layer to provide cylindrical through holes;

In S300, depositing a semiconductor material on the surface of the first Bragg reflecting layer by a metal-organic chemical vapor deposition method to form connecting parts, where the connecting parts include extending pieces and supporting pieces;

In S400, growing LED structures on the surfaces of the supporting pieces to obtain LED light sources;

In S500, providing an electrode on the surfaces of the LED light sources by a thermal evaporation method, thus forming a light-emitting layer including the LED light sources and the electrode; and

In S600, providing a second Bragg reflecting layer on the surface of the light-emitting layer.

According to the method for manufacturing the nano Bessel laser beam emitter as set forth in an embodiment of the present application, the nano Bessel laser beam emitter generated by the method is relatively small in size and facilitates integration. Meanwhile, the manufacturing method is simple, and enables the large-scale production of the nano Bessel laser beam emitters.

Specifically, as shown in FIG. 4 and FIG. 6, the growth layer 500 is deposited on the surface of the substrate 400 by the metal-organic chemical vapor deposition method, and then the first Bragg reflecting layer 100 is deposited by the plasma-enhanced chemical vapor deposition method, the low-pressure chemical vapor deposition method or the magnetron sputtering method. The first Bragg reflecting layer 100 is etched by means of electron beam lithography, inductively coupled plasma etching, nanoimprinting, or focused ion beam etching, etc., to generate the cylindrical through holes 110. Since the area of the cylindrical through holes 110 may determine the sizes of the LED light sources 210 and the size of the eventually formed light-emitting light spot, the diameters of the cylindrical through holes 110 are set between 50 nm and 300 nm. In addition, by means of electron beam lithography, inductively coupled plasma etching, nanoimprinting, or focused ion beam etching, the opening can be generated without damaging the first Bragg reflecting layer 100.

Gallium nitride is grown on the growth layer 500 corresponding to the cylindrical through holes 110 by a metal-organic chemical vapor deposition method to form the connecting parts 600, the connecting parts 600 include extending pieces 610 and supporting pieces 620, the cylindrical through holes 110 are filled with gallium nitride to form the extending pieces 610, and the supporting pieces 620 of a hexagonal frustum structure are formed above the first Bragg reflecting layer 100. The sizes of the supporting pieces 620 are larger than those of the cylindrical through holes 110, which are approximately 5 to 20 times the diameters of the cylindrical through holes 110, and between 300 nm and 1 μm. The hexagonal frustum structure can be generated by growing a hexagonal pyramid structure on the first Bragg reflecting layer 100, and then annealing at a high temperature and polishing from top to bottom with a chemical mechanical polishing method.

The LED structures are grown on the surfaces of the supporting pieces 620 by a metal-organic chemical vapor deposition method to generate the LED light sources 210. Since the area of the supporting pieces 620 is substantially less than 1 μm², the light-emitting area of the eventually grown LED is about 0.3 to 0.8 times the area of the supporting pieces 620, that is, 300 to 800 nm², and thus the manufacturing of the nano LED light sources 210 is achieved. The electrode 220 is provided on the surfaces of the LED light sources 210 by the thermal evaporation method, thereby completing the manufacturing of the light-emitting layer 200. Finally, the second Bragg reflecting layer 300 is provided on the light-emitting layer 200 at one side distal to the first Bragg reflecting layer 100, by the plasma-enhanced chemical vapor deposition method, the low-pressure chemical vapor deposition method, or the magnetron sputtering method, where the thickness of the second Bragg reflecting layer 300 is less than that of the first Bragg reflecting layer 100. Both the first Bragg reflecting layer 100 and the second Bragg reflecting layer 300 are composed of alternate layers of a high reflective material and a low reflective material, and the thickness of each layer of material can be controlled as required.

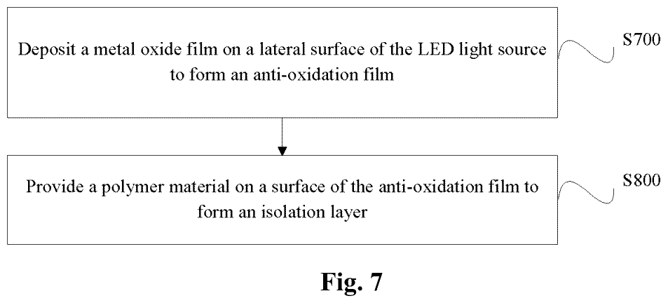

In some embodiments of the present application, as shown in FIG. 4 and FIG. 7, the method for manufacturing the nano Bessel laser beam emitter further includes, but is not limited to, the following steps.

In S700, depositing a metal oxide film on a lateral surface of each LED light sources to form an anti-oxidation film.

In S800, disposing a polymer material on a surface of each anti-oxidation film to form an isolation layer.

Specifically, the lateral surfaces of the LED light sources are coated with the metal oxide films (such as aluminum oxide) by the atomic layer deposition method, so as to form the anti-oxidation films, and the anti-oxidation films can protect the LED light sources 210, prevent the LED light sources 210 from being oxidized and damaged, and also prevent the light beams emitted by the LED light sources 210 from propagating toward both sides, so that more of the light beams can enter the first Bragg reflecting layer 100, which increases the utilization rate of the light beams. The surfaces of the anti-oxidation films are covered with a layer of polymer material, so as to form the isolation layers 800. The isolation layers 800 are disposed between two adjacent LED light sources 210, so as to prevent the light beams emitted by different LED light sources 210 from being mixed together, thereby improving the quality of the Bessel beams. The anti-oxidation films and the isolation layers 800 are both located below the electrode 220.

Embodiments of the present application have been described in detail above with reference to the accompanying drawings, but the present application is not limited to the above embodiments, and various alternations can be made within the knowledge of those skilled in the art without departing from the scope of the present application. Furthermore, embodiments of the present application and features in the embodiments may be combined with each other without conflict.

What is claimed is:

1. A nano Bessel laser beam emitter, comprising,
a first Bragg reflecting layer defining a cylindrical through hole;
a light-emitting layer provided on a surface of the first Bragg reflecting layer and configured to generate a light beam; and
a second Bragg reflecting layer provided on the light-emitting layer at a side distal to the first Bragg reflecting layer.

2. The nano Bessel laser beam emitter of claim 1, wherein each of the first Bragg reflecting layer and the second Bragg reflecting layer comprises a plurality of reflecting layers, and the first Bragg reflecting layer comprises a larger number of reflecting layers than the second Bragg reflecting layer, wherein each reflecting layer comprises a high refractive material layer and a low refractive material layer.

3. The nano Bessel laser beam emitter of claim 1, further comprising,
a substrate provided on the first Bragg reflecting layer at a side distal to the light-emitting layer.

4. The nano Bessel laser beam emitter of claim 3, further comprising,
a growth layer provided on the substrate at a side adjacent to the first Bragg reflecting layer; and
a connecting part comprising an extending piece and a supporting piece, wherein the extending piece is embedded in the cylindrical through hole of the first Bragg reflecting layer, and the supporting piece is disposed on the first Bragg reflecting layer at a side distal to the growth layer.

5. The nano Bessel laser beam emitter of claim 4, wherein the supporting piece is of a hexagonal frustum structure, and has a larger area at a surface adjacent to the growth layer than that of a surface distal to the growth layer, and the light-emitting layer is provided on the supporting piece at a surface distal to the growth layer.

6. The nano Bessel laser beam emitter of claim 1, wherein the light-emitting layer comprises,
an LED light source provided on the first Bragg reflecting layer at a side adjacent to the second Bragg reflecting layer, and corresponding to the cylindrical through hole; and
an electrode provided on the LED light sources at a side distal to the first Bragg reflecting layer, and configured to supply power to the LED light source.

7. The nano Bessel laser beam emitter of claim 6, further comprising,
an anti-oxidation layer provided between the LED light source and the electrode, and covering a lateral surface of the LED light source.

8. The nano Bessel laser beam emitter of claim 7,
wherein, the LED light source is a respective one of a plurality of LED light sources each having a respective anti-oxidation layer, and
the nano Bessel laser beam emitter further comprises,
a plurality of isolation layers each covering a surface of the anti-oxidation layer of a respective one of the plurality of LED light sources and configured to separate light beams emitted by two adjacent LED light sources of the plurality of the LED light sources.

9. A method for manufacturing a nano Bessel laser beam emitter, comprising,
sequentially providing a growth layer and a first Bragg reflecting layer on a surface of a substrate by a plasma-enhanced chemical vapor deposition method, a low-pressure chemical vapor deposition method, or a magnetron sputtering method;
etching the first Bragg reflecting layer to create a cylindrical through hole;
depositing a semiconductor material on a surface of the first Bragg reflecting layer by a metal-organic chemical vapor deposition method to form a connecting part, wherein the connecting part comprises an extending piece and a supporting piece;
growing an LED structure on a surface of the supporting piece to generate an LED light source;
providing an electrode on a surface of the LED light source by a thermal evaporation method, thus forming a light-emitting layer comprising the LED light source and the electrode; and
providing a second Bragg reflecting layer on a surface of the light-emitting layer.

10. The method of claim 9, further comprising,
depositing a metal oxide film on a lateral surface of the LED light source to form an anti-oxidation film; and
providing a polymer material on a surface of the anti-oxidation film to form an isolation layer.

11. The nano Bessel laser beam emitter of claim 4, further comprising,
The extending piece is a respective one of a plurality of extending pieces each embedded in a respective one of a plurality of cylindrical through holes.

12. The nano Bessel laser beam emitter of claim 8,
wherein, the lateral surface of the LED light source includes a left lateral surface and a right lateral surface, and the plurality of LED light sources each have the anti-oxidation layer on both the left lateral surface and the right lateral surface, and
wherein, each of the plurality of isolation layers covers the lateral surfaces of the two adjacent LED light sources of the plurality of the LED light sources facing each other.
